(19) United States
(12) Patent Application Publication
(10) Pub. No.: US 2002/0042018 A1
(43) Pub. Date: Apr. 11, 2002

(54) Positive chemically amplified resist and method for forming its pattern

(75) Inventors: Katsumi Maeda, Tokyo (JP); Shigeyuki Iwasa, Tokyo (JP); Kaichiro Nakano, Tokyo (JP); Etsuo Hasegawa, Tokyo (JP)

Correspondence Address: Norman P. Soloway, HAYES, SOLOWAY, HENNESSEY, GROSSMAN & HAGE, P.C., 175 Canal Street, Manchester, NH, 03101, US

(73) Assignee: NEC Corporation

(21) Appl. No.: 09/921,624

(22) Filed: Aug. 3, 2001

(30) Foreign Application Priority Data
Aug. 3, 2000 (JP) 2000-236106

(51) Int. Cl. G03F 7/038; G03F 7/38; G03F 7/40; G03F 7/30

(52) U.S. Cl. 430/270.1; 430/330; 430/325

(57) ABSTRACT

A form-improvement agent, for resist pattern, including a steroid compound is included in a positive chemically amplified resist. The form-improvement agent is in a range from 0.5 to 8 parts by weight per 100 parts by weight of a resin for resist included in the positive chemically amplified resist. The steroid compound is, for example, a cholic acid ester.

### BACKGROUND OF THE INVENTION

1. Field of the Invention

The present invention relates to a positive chemically amplified resist which is exposed to far ultraviolet rays whose wavelengths are equal to smaller than 220 nm, and a method for forming its pattern, and, more particularly, to a positive chemically amplified resist having excellent adhesiveness to substrate and having a pattern which is prevented from being deteriorated, and a method for forming the pattern.

2. Description of the Related Art

In the field of manufacture of electronic devices, typically semiconductor devices, which need to finely and minutely be formed in the half micron order, it is demanded that high density and highly integrated electronic devices are formed. Hence, it is highly demanded that a photolithography technique for minutely and finely forming patterns for the devices should further be advanced.

Recently, for manufacturing Giga-bit DRAMs (Dynamic Random-Access Memory) (processing size of 0.15 μm or smaller), there is proposed a photolithography technique using an ArF excimer laser whose wavelength is 193 nm (Donald C. Hoffer, et al., Journal of Photopolymer Science and Technology, 1996, Vol. 9, No. 3, pp 387-397).

It is desired that a resist material suitable for the photolithography using the ArF light is developed. The resist for the ArF exposure needs to be developed based upon cost and performance considerations of the laser, because the laser gas lasts for a short period of time and the laser unit itself is expensive. Thus, it is demanded that the resist should be formed to have high-sensitivity characteristic in addition to its high-resolution characteristic corresponding to the finely integrated structure.

In a well-known method for increasing the sensitivity of the resist, a chemically amplified resist including a photoacid generator as a photosensitive agent is employed. One typical example of such a method is disclosed in Unexamined Japanese Patent Application KOKAI Publication No. H2-27660. In this method, a resist which is composed of a combination of triphenylsulfonium hexafluoroarsenate and poly (p-tert-butoxycarbonyloxy-α-methylstyrene) is used. This chemically amplified resist is nowadays widely used as a resist for a KrF excimer laser whose wavelength is 248 nm (Hiroshi Ito & C. Grant Willson, American Chemical Society Symposium Series, 1984, Vol. 242, pp 11-23.) Chemically amplified resists are characterized in that a photoacid generator serving as the resist component generates a protonic acid by light irradiation and the acid causes acid-catalyzed reaction with a resist resin, etc. through thermal treatment after exposure. Thus, sensitivity is dramatically enhanced compared with the case of a conventional resist having photoreaction efficiency (occurrence of reaction caused by one photon) of less than one. At the present time, most developed resists are of the chemically amplified type.

However, in the case of lithography using light having a wavelength as short as 220 nm or less, typically an ArF excimer laser, a resist for forming micro-patterns must have new characteristics which conventional resist materials cannot possess, i.e., high transparency to exposure light having a wavelength of 220 nm or less and dry-etching resistance.

Conventional positive photoresists for g-line (438 nm), i-line (365 nm), and KrF excimer laser (248 nm) are mainly formed of a resin, wherein a resin having an aromatic ring in the structural unit such as a novolak resin or poly (p-vinylphenol) is used as the resin component. Etching resistance of the resin is maintained due to the dry-etching resistance of the aromatic ring. However, resins having an aromatic ring exhibit strong photoabsorption to light having a wavelength of 220 nm or less. In this structure, because the exposure light is mostly absorbed at the resist surface, the light does not reach the substrate. Hence, the resist pattern can minutely be formed. Therefore, conventional resins cannot be adapted to photolithography employing light having a wavelength as short as 220 nm or less. Accordingly, strong need exists for photoresist materials having no aromatic ring, being endowed with etching resistance, and exhibiting a low level of photoabsorption to light having a wavelength of 220 nm or less.

As polymer compounds having transparency to an ArF excimer laser (193 nm) and dry-etching resistance there have been proposed alicyclic polymers such as a copolymer having an adamantyl methacrylate unit (Takechi et al., Journal of Photopolymer Science and Technology, 1992, Vol. 5, No. 3, pp 439-446), a copolymer having an isobornyl methacrylate unit (R. D. Allen et al., Journal of Photopolymer Science and Technology, 1995, Vol. 8, No. 4, pp 623-636 and 1996, Vol. 9, No. 3, pp 465-474), and a resin having an alternating copolymer unit of norbornene and maleic anhydride (F. M. Houlihan, et al., Macromolecules, 1997, Vol. 30, pp 6517-6524).

The resist for ArF excimer laser includes a resin having an alicyclic hydrocarbon group. In this structure, the resins are hard, therefore, a problem arises in that the resist pattern is likely to be deteriorated. Further, such a problem is caused by their hydrophobic property and low adhesiveness to a target substrate to be processed (e.g. a silicon substrate, etc.). In the above circumstances, there exists need for a resist material including alicyclic resins, whose pattern is prevented from being deteriorated and high adhesiveness to the substrate.

### SUMMARY OF THE INVENTION

The present invention has been made in consideration of the above. It is accordingly an object to provide a positive chemically amplified resist, using far ultraviolet rays at a wavelength equal to or less than 220 nm and having high adhesiveness to the substrate, and whose pattern is prevented from being deteriorated, and a method for forming its pattern.

In order to achieve the above object, according to the first aspect of the present invention, there is provided a positive chemically amplified resist comprising:

a photoacid generator for generating an acid upon exposure to a ray of light;

a resin, for resist, which includes an acid-decomposable group to be decomposed by an acid and whose solubility in an alkali aqueous solution increases as a result that the acid-decomposable group is decomposed by an acid; and

a form-improvement agent, for resist pattern, which includes a steroid compound, and

wherein the form-improvement agent is in a range from 0.5 to 8 parts by weight per 100 parts by weight of the resin for resist.

In this invention, a predetermined weight of the form improvement agent for the resist pattern is included in the positive chemically amplified resist.

The steroid compound may be expressed by a following chemical formula 1, where R represents an acid-decomposable group and each of R¹, R², R³, and R⁴ represents either one of a hydrogen atom, a hydroxyl group, an alkoxy group, and an acetoxy group.

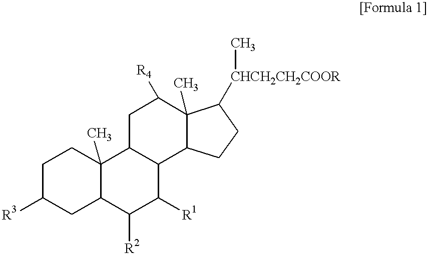

The resin for resist may have an alicyclic lactone structure.

The resist for resin may have a C₇-to-C₁₃ bridged cyclic hydrocarbon group having a group decomposable by an acid.

The resin for resist may have both an alicyclic lactone structure and a C₇-to-C₇-to-C₁₃ bridged cyclic hydrocarbon group having a group decomposable by an acid.

The resin for resist may be expressed by a following chemical formula 2 where:

each of R⁵, R⁶, R⁷ and R⁸ represents a hydrogen atom or a methyl group;

R⁹ represents a group being decomposed by an acid or a C₇-to-C₁₃ bridged cyclic hydrocarbon group having a group decomposable by an acid;

R¹⁰ represents a hydrogen atom, a hydrocarbon composed of one to twelve carbons, or C₇-to-C₁₃ bridged cyclic hydrocarbon group having a carboxyl group;

and x, y, and z are arbitrary numbers which satisfy conditions of x+y+z=1, 0≦x<1, 0<y<1, 0≦z<1.

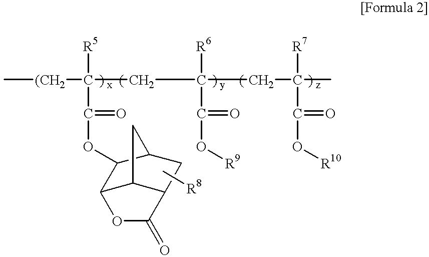

In order to achieve the above object, according to the second aspect of the present invention, there is provided a method for forming a pattern on a positive chemically amplified resist, the method comprising:

applying the above-described positive chemically amplified resist onto a target substrate to be processed;

pre-baking the positive chemically amplified resist applied onto the target substrate;

exposing the pre-baked positive chemically amplified resist to light whose wavelength is within a range between 130 nm and 220 nm;

baking the positive chemically amplified resist which is exposed to the light; and

developing the baked positive chemically amplified resist.

As the exposure light at the wavelength in the range from 130 to 220 nm, an ArF excimer laser at a wavelength of 193 nm or an F₂ excimer laser at a wavelength of 157 nm may be used.

### BRIEF DESCRIPTION OF THE DRAWINGS

The object and other objects and advantages of the present invention will become more apparent upon reading of the following detailed description and the accompanying drawings in which:

FIG. 1 is a cross sectional view showing the form of a resist pattern made in an example No. 1 of an embodiment of the present invention;

FIG. 2 is a cross sectional view showing the form of a resist pattern made in an example No. 4; and

FIG. 3 is a cross sectional view showing the form of a resist pattern made in an example No. 6.

### DETAILED DESCRIPTION OF THE PREFERRED EMBODIMENT

A preferred embodiment of the present invention will now be explained with reference to the accompany drawings.

A positive chemically amplified resist of this embodiment includes: a photoacid generator for generating an acid upon exposure to light; a resin (for resist) having an acid-decomposable group, and whose solubility in an alkali aqueous solution increases as a result that the acid-decomposable group is decomposed by an acid; and a form improvement agent for a resist pattern and including a steroid compound.

The steroid compound used as the form improvement agent has the structure of the following chemical Formula 1. The steroid compound is, for example, a cholic acid, a deoxycholic acid, an α-hyodeoxycholic acid, a lithocholic acid, a ursodeoxycholic acid, a cholanic acid, or a derivative of those. Specifically, cholic acid ester is a group, wherein R is decomposed by acid as illustrated in Formula 1, and R¹ to R⁴ represent a hydroxyl group. In this structure, the form of the resist pattern can be improved, and the adhesiveness between the substrate and the resist pattern can be improved.

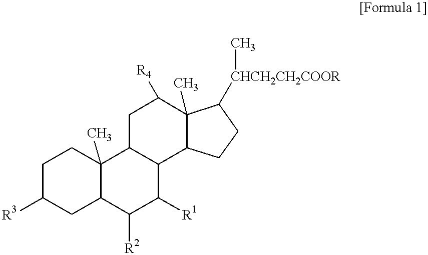

In the above Formula 1, R is a group decomposable by an acid. Particularly, R may, for example, be a t-butyl group, a tetrahydropyran-2-yl group, a tetrahydrofuran-2-yl group, a 4-methoxytetrahydropyran4-y group, a 1-ethoxyethyl group, a 1-butoxyethyl group, a 1-propoxyethyl group, a 3-oxocyclohyxyl group, a 2-methyl-2-adamantyl group, a 2-ethyl-2-adamantyl group, an 8-methyl-8-tricyclo [5.2.1.0^{2.6}] decyl group, a 1,2,7,7-tetramethyl-2-norbornyl group, a 2-acetoxymenthyl group, a 2-hydroxymenthyl group, a 1-methyl-1-cyclohexylethyl group, etc. Each of R¹, R², R³, and R⁴ represents either one of a hydrogen atom, a hydroxyl group, an alkoxy group, and an acetoxy group. Particularly, the alkoxy group may be a methoxy group, an ethoxy group, a propoxy group, or a butoxy group.

It is necessary that the form improvement agent, included in the positive chemically amplified resist of this embodiment, is from 0.5 to 8 parts by weight per 100 parts by weight of the resin for resist. The form of the resist pattern can be expected to be improved, when the form improvement agent is equal to or higher than 0.5 parts by eight per 100 parts by weight of the resin. However, if the form improvement agent is equal to higher than 8 parts by weight per 100 parts by weight of the resin, a problem arises in that the contrast of the resist decreases, and that the resolution of the resist decreases.

The resin for resist employed in this embodiment has high transparency for the light in a range from far ultraviolet rays to vacuum ultraviolet rays of light having a wavelength lower than 220 nm to a wavelength. In addition, an adequate amount of resin which is solubilized in an alkali developer by an acid can be employed. The resin is from 60 to 99.8 parts by weight, or more preferably in a range from 75 to 99 parts by weight, per 100 parts by weight of the entire resist, excluding the solvents included in the resist.

One example of the resin for resist, which is preferable in the positive chemically amplified resist of this embodiment, is a resin having a C₇-to-C₁₃ bridged cyclic hydrocarbon group, which is composed of seven to thirteen carbon atoms, having a group decomposable by an acid. Such a type of resin includes a copolymer disclosed in Japanese Patent Publication No. 2856116. This copolymer has an alicyclic (meth) acrylate unit having a group decomposable by an acid. The entire disclosure of the above publication is incorporated herein by reference in its entirety.

In this embodiment of the present invention, a resin for resist having an alicyclic lactone structure in its resin structure may be employed. Such a resin may be a copolymer having a (meth) acrylate unit having a 2,6-norbornanecarbolactone group which is disclosed in Japanese Patent Publication No. 3042618, or a resin which is disclosed in Journal of Photopolymer Science and Technology, 2000, Vol. 13, No. 4, pp 601-606. The disclosures of the above publication and journal article are incorporated herein by reference.

Further, as the resin for resist, there may be employed a resin having both the alicyclic lactone structure in its resin structure and a C₇-to-C₁₃ bridged cyclic hydrocarbon group having a group decomposable by an acid.

In addition, as the resin for resist, there may be employed a resin which is expressed in Formula 2, on the following four conditions (1) to (4). (1) Each of R⁵, R⁶, R⁷ and R⁸ represents a hydrogen atom or a methyl group. (2) R⁹ represents a group being decomposed by an acid or a C₇-to-C₁₃ bridged cyclic hydrocarbon group having a group decomposable by an acid. (3) R¹⁰ represents a hydrogen atom, a hydrocarbon composed of one to twelve carbons, or C₇-to-C₁₃ bridged cyclic hydrocarbon group having a carboxyl group. (4) x, y, and z are arbitrary numbers which satisfy x+y+z=1, 0≦x<1, 0<y<1, 0≦z<1.

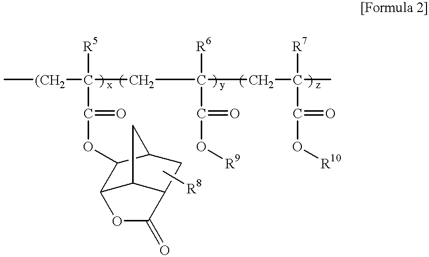

Furthermore, as the resin for resist, there may be employed a copolymer having a 2-alkyladamantyl (meth) acrylate unit and being disclosed both in Journal of Photopolymer Science and Technology, 1997, Vol. 10, No. 4, pp 545-550 and in Unexamined Japanese Patent Application KOKAI Publication No. H9-73173. The disclosure of the article in the above-indicated journal and the disclosure of the above publication are incorporated herein by reference.

Additionally, as the resin for resist, there may be employed a resin having an alternating copolymer unit of norbornene and maleic anhydride and disclosed in Journal of Photopolymer Science and Technology, 1997, Vol. 10, No. 3, pp 511-520 and in Journal of Photopolymer Science and Technology, 1998, Vol. 11, No. 3, pp 481-488. The disclosures of the above-indicated journal articles are incorporated herein by reference.

Further, as the resin for resist, there may be employed: a resin having an alternating copolymer unit of tetracyclododecene derivative and maleic anhydride and disclosed in Journal of Photopolymer Science and Technology, 1999, Vol. 12, No. 4, pp 553-559; a polynorbornene derivative disclosed in Unexamined Japanese Patent Application KOKAI Publication No. H10-218941 and in Journal of Photopolymer Science and Technology, 1998, Vol. 11, No. 3, pp 475-480; a resin which can be obtained by ring-opening metathesis polymerization of a norbornene derivative or tetracyclododecene derivative which are both disclosed in Unexamined Japanese Patent Application KOKAI Publication No. H10-111569; a resin disclosed in Unexamined Japanese Patent Application KOKAI Publication No. H11-305444 and having both an alternating copolymer unit of norbornene and maleic anhydride and a 2-alkyladamantyl (meth) acrylate unit; or a copolymer having a (meth) acrylate unit having the lactone structure and disclosed in Unexamined Japanese Patent Application KOKAI Publication No. H11-295894. The disclosures of the above-indicated journal articles and publications are incorporated herein by reference.

Any resins other than the above-described positive resist resins can preferably be used, as long as the resins have high transparency for rays of light whose wavelength is lower than 220 nm and react with an acid catalyst.

It is preferred that the average molecule weight of the resin for resist be in a range between 2,000 and 200,000, and more preferred that the average molecule weight thereof be in a range between 3,000 and 100,000. If the average molecule weight of the resin is equal to or larger than 2,000, the resist film can easily be formed. On the contrary, if the average molecule weight of the resin is equal or less than 200,000, the solubility of the resin in the solvent is increased, and the resolution characteristics of the resin will be better off.

The photoacid generator for use in the positive chemically amplified resist of this embodiment generates an acid upon exposure to rays of light whose wavelength is equal to or less than 400nm, more preferably in a range between 130 and 220 nm. In addition, the photoacid generator may be any kind of photoacid generator, as long as the compounds including the resist resin sufficiently dissolves in an organic solvent, and a film can evenly be formed using a spin coating technique with the solution. Further, the photoacid generator may be of one type, or two or more types of photoacid generators may be used in combination with each other.

For example, the photoacid generator may be: triphenylsulfonium salt derivative disclosed in Journal of the Organic Chemistry, 1978, Vol. 43, No. 15, pp 3055-3058 by J. V. Crivello, et al; onium salts (e.g. sulfonium salts, iodonium salts, phosphonium salts, diazonium salts, and ammonium salts); 2,6-dinitrobenzylester group (S.P.I.E. Proceeding, 1994, Vol. 2195, p 137, by 0. Nalamasu, et al.); 1, 2, 3-tri (methanesulfonyloxy) benzene (Proceeding of PME' 89, 1990, Kodansha Ltd., pp 413-424, by Takumi Ueno, et al.); sulfosuccinimide disclosed in Unexamined Japanese Patent Application KOKAI Publication No. H5-134416; and alkylsulfonium salts disclosed in Japanese Patent Publication No. 2964990. The disclosures of the above journals and publications are incorporated herein by reference.

It is preferred that the photoacid generator be in a range from 0.2 to 30 parts by weight, more preferably in a range 1 to 15, per 100 parts by weight of the positive chemically amplified resist excluding the solvent. Specifically, if the photoacid generator is equal to or larger than 0.2 parts by weight per 100 parts by weight of the positive chemically amplified resist excluding the solvent, a sufficient level of sensitivity of the resist can be obtained and the resist pattern can easily be formed. On the contrary, if the photoacid generator is equal to or less than 30 parts by weight per 100 parts by weight of the chemically amplified resist excluding the solvent, the film can evenly be formed, and the resist is unlikely to be left while developed resist is removed, i.e. scumming is unlikely to occur.

The positive chemically amplified resist of this embodiment includes an adequate amount of solvent, in addition to the resin, photoacid generator, and pattern-form improvement agent. This solvent is usually an organic solvent. The type of the organic solvent is arbitrary, as long as the components containing the resin, photoacid generator, and pattern-form improvement agent can evenly be dissolved in the solvent, and the film can evenly be formed using a spin coating technique. The organic solvent for use in the positive chemically amplified resist may be of one or two or more than two types of organic solvents in combination with each other. Specifically, it is preferred that the organic solvent be: an alcohol group, such as n-propyl alcohol, isopropyl alcohol, n-butyl alcohol, and tert-butyl alcohol; an ester group, such as methylcellosolve acetate, ethylcellosolve acetate, propylene glycol monoethyl ether acetate, lactate methyl, lactate ethyl, acetic acid 2-methoxybutyl, acetic acid 2-ethoxybutyl, pyruvic acid methyl, pyruvic acid ethyl, 3-methoxypropiolic acid methyl, and 3-methoxypropiolic acid ethyl; a ring-ketone-alcohol group, such as N-methyl-2-phlorizinone, cyclohexanone, cyclopentanone, and cyclohexanol; a ketone group such as methylethylketone, etc.; and a glycol ether group, such as 1,4-dioxan, ethylene glycol monomethyl ether, ethylene glycol monomethyl ether acetate, ethylene glycol monoethyl ether, ethylene glycol monoisopropyl ether, diethylene glycol monomethyl ether, and diethylene glycol dimethyl ether, etc. However, the organic solvent is not limited to the above examples.

The element components of the positive chemically amplified resist of this invention include the above resist resin, photoacid generator, pattern-form improvement agent. In addition to the above, the positive chemically amplified resist may include any other component(s), such as an organic salt group, a surface-active agent, a pigment, a fixing agent, an applicable improvement agent, and dye(s).

According to the pattern formation method of the present invention, the resist is exposed to rays of light whose wavelength is in a range between 130nm and 220nm, and a mask pattern is transferred onto the resist-applied film, using the positive chemically amplified resist. In this method, a resist application process, a baking process before light exposure, a baking process after light exposure, and a developing process are substantially the same as those included in the conventional pattern formation method which employs the chemically amplified resist.

### EXAMPLES

Explanations will now be made to the resist employed in the embodiment of the present invention in comparison with some examples. Those examples will be explained for descriptive purposes only, and the present invention is not limited to those.

A resin for resist is compounded from the following components. In a 100 ml flask, 5-acryloyloxy-2,6-norbornanecarbolactone 6 g (0.0288 molar), t-butoxylcarbonyl tetracyclododecyl acrylate 11.975 g (0.036 molar), and carboxytetracyclododecyl methacrylate 2.193 g (0.0072 molar) are all dissolved into dry tetrahydrofuran (100 ml). In this flask, azobisisobutyronitrile 473 mg (4 molar %) is further added and reacted with the above-described components for four hours at a temperature in a range from 60° C. to 65° C. under argon atmosphere. After that, the solution is cooled down, and the cooled solution drips down to a solution (1,000 ml) including ligroin and toluene mixed with each other in a ratio of 4 to 1, and deposited polymer is filtered. Then, the solution is again purified, thereby to obtain white polymer 13.31 g (66% yield). This realizes in obtaining the resin for resist which has the structure of chemical Formula 3.

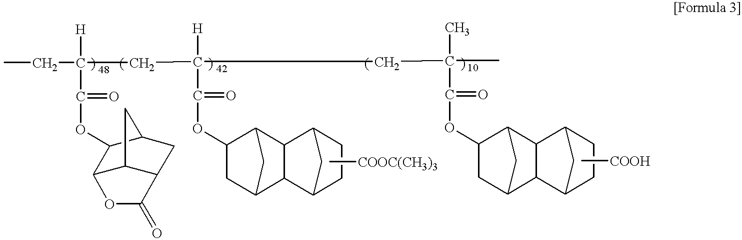

With thus composed resin for resist, the resist according to this embodiment and some comparative resists are adjusted. Specifically, triphenylsulfonium nonaflate (0.04 g) as a photoacid generator and tributylamine (0.004 g) as an organic salt group are added to the resist resin 2g having the structure of the above formula 3. Further, cholic acid t-butyl ester (hereinafter referred to as CHB) as a form improvement agent is added to the resist resin. The amount of CHB to be added to the resist resin is noted in a Table 1. Propylene glycol monoethyl ether acetate is added to the above solid components of he resist resin, etc., such that the weight percentage of the solid material thereof, is 14%. These compounds are filtered by a Teflon filter having a thickness of 0.2 μm, so as to prepare the resist.

Using this resist, the patterning of the resist is evaluated. An organic antireflective agent (e.g. “DUV30J” manufactured by Brewer Science Inc.) is applied on an eight-inch silicon substrate, and the resist is spin-coated on this substrate. Then, the substrate is baked on a hot-plate for a minute at a temperature of 110° C., so as to form a thin film of 0.4 μm. The thin film (resist) is exposed to light using an ArF exposure device (NA=0.6). Immediately after this, the resist (substrate) is baked on the hot plate for sixty seconds at a temperature of 110° C., and developed for sixty seconds using a 2.38% TMAH water solution at a liquid temperature of 23° C. Subsequently, the substrate is rinsed with pure water. Shown in the Table 1 are results of the resist patterning.

TABLE 1

| | | Amount of CHB (parts | | | | |
|---|---|---|---|---|---|---|
| | | by weight per 100 parts | Resolution | Sensitivity | | |
| | No | by weight of resin) | (μmL/S) | (mJ/cm²) | Pattern Form | Drawing |
| Example | 1 | 3 | 0.14 | 16 | Rectangular | |
| | 2 | 6 | 0.15 | 23.5 | Rectangular | — |
| | 3 | 8 | 0.15 | 26 | Rectangular | — |
| Comparative | 4 | 0 | 0.15 | 10.9 | Pattern | |
| Example | | | | | Deterioration | |
| | 5 | 10 | 0.175 | 34 | Taper | — |
| | 6 | 15 | 0.20 | 40 | Taper | |

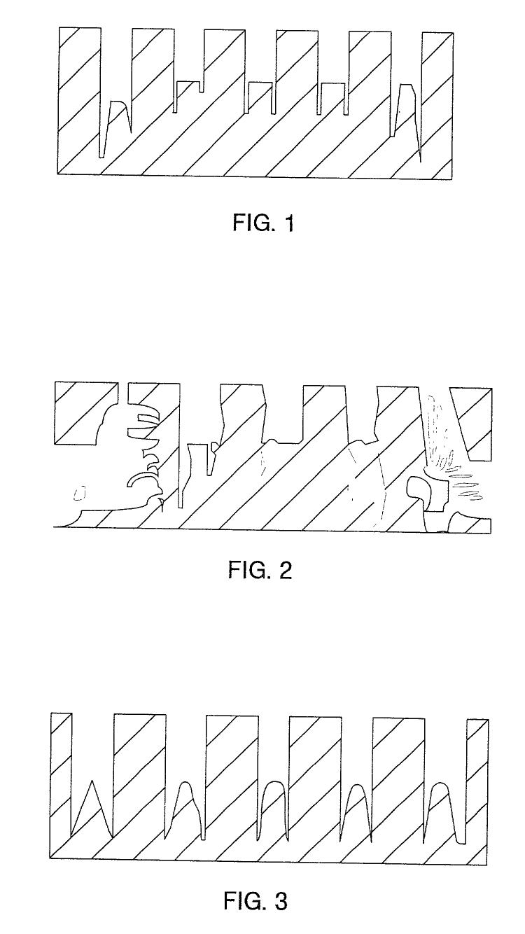

In Table 1, No. 1 to No. 3 indicate the examples of the present invention. FIG. 1 is a cross sectional view showing the pattern form of the resist in the example No. 1. FIG. 1 exemplarily shows a photographic image of the pattern form taken using an SEM (Scanning Electron Microscope). In terms of the examples No. 1 to 3, the amounts of added CHB are within a predetermined range which is set in the present invention. Hence, the rectangular pattern form of the resist in a thickness of 0.14 μmL/S is securely obtained, without being deteriorated. In addition, in terms of the examples 1 to 3, the adhesiveness between the resist and the substrate is satisfactory.

In Table 1, Nos. 4 to 6 indicate the comparative examples. FIGS. 2 and 3 are cross sectional views showing the pattern forms of the resists in the comparative examples No. 4 and 6, respectively. FIGS. 2 and 3 also exemplarily show photographic images of the pattern forms taken using an SEM. As seen from FIG. 2, both end patterns of the resist in the comparative example No. 4 are deteriorated in the patterning of 0.15 μmL/S, since CHB has not been added to the resist. From this result, it is pointed out that if CHB is not added to the resist, the pattern deterioration occurs.

As shown in FIG. 3, in the comparative examples Nos. 5 and 6, large amounts of CHB are added to the resists. Hence, in the patterning of 0.2 μm/S, the pattern form of the resist is taper (triangle). From this result, if a large amount of CHB is added to the resist, the contrast of the resist is decreased, and the resolution thereof gets decreased.

From the above results, a predetermined amount of form-improvement agent for the resist pattern is added to the resist, thereby the pattern form of the resist pattern can adequately be obtained and the adhesiveness between the resist and the substrate can be satisfactory. Further, it is obvious that the resolution characteristics of the resist can be improved.

As specifically explained above, according to the embodiment of the present invention, an adequate amount of the form-improvement agent for resist pattern is included in the positive chemically amplified resist which is exposed to far ultraviolet rays whose wavelength is equal to smaller than 220 nm. This realizes a positive chemically amplified resist having an excellent resist pattern and high adhesiveness to the substrate. Accordingly, the resist pattern necessary for manufacturing semiconductor devices can be finely formed.

Various embodiments and changes may be made thereonto without departing from the broad spirit and scope of the invention. The above-described embodiments are intended to illustrate the present invention, not to limit the scope of the present invention. The scope of the present invention is shown by the attached claims rather than the embodiment. Various modifications made within the meaning of an equivalent of the claims of the invention and within the claims are to be regarded to be in the scope of the present invention.

This application is based on Japanese Patent Application No. 2000-236106 filed on Aug. 3, 2000, and including specification, claims, drawings and summary. The disclosure of the above Japanese Patent Application is incorporated herein by reference in its entirety.

What is claimed is:

1. A positive chemically amplified resist comprising:
a photoacid generator for generating an acid upon exposure to a ray of light;
a resin, for resist, which includes an acid-decomposable group to be decomposed by an acid and whose solubility in an alkali aqueous solution increases as a result that the acid-decomposable group is decomposed by an acid; and
a form-improvement agent, for resist pattern, which includes a steroid compound, and
wherein the form-improvement agent is in a range from 0.5 to 8 parts by weight per 100 parts by weight of the resin for resist.

2. The positive chemically amplified resist according to claim 1, the steroid compound can be expressed by a following chemical formula 1, where R represents an acid-decomposable group and each of R¹, R², R³, and R⁴ represents either one of a hydrogen atom, a hydroxyl group, an alkoxy group, and an acetoxy group.

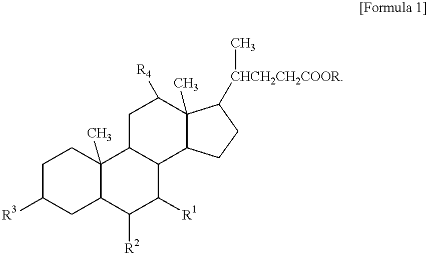

3. The positive chemically amplified resist according to claim 1, wherein the resin for resist has an alicyclic lactone structure.

4. The positive chemically amplified resist according to claim 2, wherein the resin for resist has an alicyclic lactone structure.

5. The positive chemically amplified resist according to claim 1, wherein the resist for resin has a C₇-to-C₁₃ bridged cyclic hydrocarbon group having a group decomposable by an acid.

6. The positive chemically amplified resist according to claim 2, wherein the resin for resist has a C₇-to-C₁₃ bridged cyclic hydrocarbon group having a group decomposable by an acid.

7. The positive chemically amplified resist according to claim 1, wherein the resin for resist has both an alicyclic lactone structure and a C₇-to-C₁₃ bridged cyclic hydrocarbon group having a group decomposable by an acid.

8. The positive chemically amplified resist according to claim 2, wherein the resin for resist has both an alicyclic lactone structure and a C₇-to-C₁₃ bridged cyclic hydrocarbon group having a group decomposable by an acid.

9. The positive chemically amplified resist according to claim 1, wherein the resin for resist can be expressed by a following chemical formula 2 where:
each of R⁵, R⁶, R⁷ and R⁸ represents a hydrogen atom or a methyl group;
R⁹ represents a group being decomposed by an acid or a C₇-to-C₁₃ bridged cyclic hydrocarbon group having a group decomposable by an acid;
R¹⁰ represents a hydrogen atom, a hydrocarbon composed of one to twelve carbons, or C₇-to-C₁₃ bridged cyclic hydrocarbon group having a carboxyl group; and x, y, and z are arbitrary numbers which satisfy conditions of x+y+z=1, 0≦x<1, 0<y<1, and 0≦z<1.

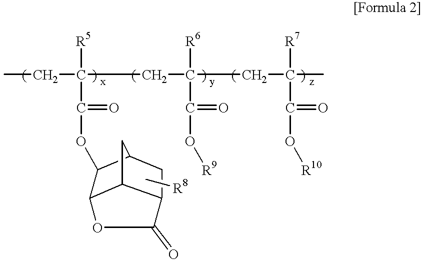

10. The positive chemically amplified resist according to claim 2, wherein the resin for resist can be expressed by a following chemical formula 2 where:
each of R⁵, R⁶, R⁷ and R⁸ represents a hydrogen atom or a methyl group;
R⁹ represents an acid decomposition group or a C₇-to-C₁₃ bridged cyclic hydrocarbon group having a group decomposable by an acid;
R¹⁰ represents a hydrogen atom, a hydrocarbon composed of one to twelve carbons, or C₇-to-C₁₃ bridged cyclic hydrocarbon group having a carboxyl group; and x, y, and z are arbitrary numbers which satisfy conditions of x+y+z=1, 0≦x<1, 0<y<1, and 0≦z<1.

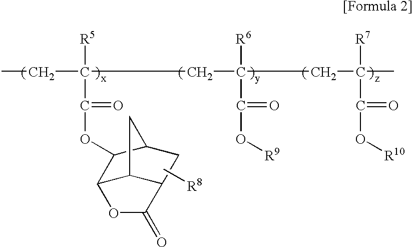

11. A method for forming a pattern on a positive chemically amplified resist, said method comprising:
applying said positive chemically amplified resist according to any one of claims 1 to 10 onto a target substrate to be processed;
pre-baking said positive chemically amplified resist applied onto the target substrate;
exposing the pre-baked positive chemically amplified resist to light whose wavelength is within a range between 130 nm and 220 nm;
baking the positive chemically amplified resist which is exposed to the light; and
developing the baked positive chemically amplified resist.

12. The method according to claim 11, wherein the light is an ArF excimer laser.
